(19) United States
(12) Patent Application Publication
(10) Pub. No.: US 2007/0001309 A1
(43) Pub. Date: Jan. 4, 2007

(54) Semiconductor device having multiple-layered interconnect

(75) Inventor: Yoshihisa Matsubara, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATIO, KANAGAWA (JP)

(21) Appl. No.: 11/476,050

(22) Filed: Jun. 28, 2006

(30) Foreign Application Priority Data
Jun. 29, 2005 (JP) 2005-189847

(51) Int. Cl. H01L 23/52

(52) U.S. Cl. 257/758

(57) ABSTRACT

A semiconductor device having a configuration, which provides a prevention from a disconnection occurred by a setback of an interconnect that is caused in a microinterconnect having a linewidth of equal to or smaller than 0.1 μm connected through a via is provided. An insulating film 204 is formed on a silicon substrate 203, and an M1 interconnect 103 and an M2 interconnect 104 are alternately disposed in this region, and these interconnects are connected through the vias 105. Here, widths of the M1 interconnect 103 and the M2 interconnect 104 are all 70 nm, which is the minimum linewidth. In such structure, the via 105 has a width, which is the same as the minimum linewidth of the M1 interconnect 103 and the M2 interconnect 104, and that the M1 interconnect 103 and the M2 interconnect 104 are commonly connected through a plurality of vias 105.

This application is based on Japanese patent application No. 2005-189,847, the content of which is incorporated hereinto by reference.

### BACKGROUND

1. Field of the Invention

The present invention relates to a semiconductor device having a microinterconnect that connects a macro circuit to another macro circuit.

2. Related Art

Test patterns generally employed for evaluating processes of semiconductor devices will be described. A general view of a layout of a test chip generally employed for evaluating processes is shown in FIG. 7. Maximum dimensions of a width 801 and a length 802 of a test chip are generally defined by field sizes of a lithography apparatus. The pattern for evaluation is configured of ensemble of evaluation blocks, which are referred to as sub chips 803, and sizes of such sub chips 803 are identical in a test block. The reason of having identical size is that the identical sizes provide identical arrangement and transfers of measurement probes in a program for measurement, so that a measurement program and/or a measurement probe can be commonly employed. Subsequently, an outline of a pattern for evaluating an interconnect process will be described in reference to FIG. 8. A pattern for evaluating interconnects process has via chains, patterns for evaluating electro migration and patterns for measuring leakage or the like. In the via chain, it is general that a scale of the pattern is determined according to length of the interconnect to be evaluated or number of the via to be evaluated. Density of defects can also be evaluated by employing patterns having different scales. An evaluation block required for conducting such process evaluations is referred to as a test element group (TEG) region 901. An electrode being in contact with a probe for electrical measurement is referred to an electrode pad 902, and an interconnect connecting the TEG region 901 and the electrode pad 902 is referred to a drawing interconnect 903.

An enlarged view of a region for connecting the TEG region to the electrode pad is shown in FIG. 9. A via chain pattern 1001 in the TEG region is, for example, electrically connected to the electrode pad (not shown) through a drawing interconnect 1002, as shown FIG. 9.

An enlarged plan view of a portion of coupling to the via chain portion of the drawing interconnect shown in FIG. 9 is shown in FIG. 10. As shown in FIG. 10, in a region closer to the via chains, the interconnect 1102 connected to the via chain portion 1101 is formed to have a linewidth that is same as the linewidth of the via chain portion 1101.

An enlarged plan view of an interconnect connected to a designated pad interconnect is shown in FIG. 11. As shown in FIG. 11, for example, a test pattern is composed of a TEG region for evaluating a via chain 1201 and a drawing interconnect region 1202 for providing an electrical coupling to a pad. The TEG region 1201 is formed of a structure, in which an M1 interconnect 1203 and an M2 interconnect 1204 are alternately disposed and these interconnects are connected through the vias 1205. In this related art, the upper layer of two layers is called M1, and a lower layer is called M2. Here, widths of the M1 interconnect 1203 and the M2 interconnect 1204 are all 70 nm, which are the minimum linewidth indicated by a numeral number of 1206. The linewidth of the M1 interconnect 1203 connected to the pad is the minimum linewidth 1206 in a coupling end of the interconnect, and an isolated interconnect unit is stepwise increased in a portion disposed as a single interconnect, and the linewidth 1207 of such portion around 0.17 μm.

A cross-sectional view of the test pattern shown in FIG. 11 is shown in FIG. 12. As shown in FIG. 12, an insulating film 1304 is formed on a silicon substrate 1303, and the M1 interconnect 1203 and the M2 interconnect 1204 are alternately disposed in such region, and these interconnects are connected through the vias 1205. Here, width of the M1 interconnect 1203 and width of the M2 interconnect 1204 are all 70 nm, which are the minimum linewidth. An allowance located in an end of the M1 interconnect 1203 and a via 1205 is referred to an extension 1308 shown in FIG. 12.

Subsequently, a general process for forming a dual-layered interconnect will be described. FIGS. 13A to 13E are cross-sectional views of a silicon substrate, illustrating main process steps.

First of all, a first interlayer insulating film 1402 including a silicon oxide film is formed on a silicon substrate 1401 via a chemical vapor deposition (CVD) process or the like (FIG. 13A). Then, a resist 1403 to be employed for a first photolithographic process is formed on the first interlayer insulating film 1402, and the formed resist is patterned via the first photolithographic process (FIG. 13B). Further, the pattern of the patterned resist is transferred to the first interlayer insulating film 1402 via a dry etching technology, and thereafter, the resist 1403 is stripped to form a trench 1404 for interconnect in a desired location (FIG. 13C).

Next, a conductor film 1405 composed of copper, aluminum or the like is deposited on the entire surface of the first interlayer insulating film 1402 including the trench 1404 for interconnect via CVD process or the like (FIG. 13D), and thereafter, the surface of the conductor film 1405 is planarized via a chemical mechanical polishing (CMP). As a result, a first interconnect 1406 is formed to have a damascene interconnect structure in a desired location of the first interlayer insulating film 1402 (FIG. 13E).

Next, related configurations in general CPU logic circuits will be described. Since an interconnect structure for coupling one isolated circuit block to an electrically close-packed circuit block is employed for a drawing interconnect for process evaluation in the TEG, and since a similar interconnect structure is also employed for finished products, a typical example of the interconnect structure of the related art is described.

A finished product comprises an input/output (I/O) block, a random access memory (RAM) block, a logic unit block and a phase locked loop (PLL) block, which provide four macro-functions. The outline thereof is shown in FIG. 14.

As shown in FIG. 14, an I/O block 1501 is an area composed of only interconnects having linewidth of not smaller than 1 μm. Narrower interconnect is not primarily required for composing the I/O block 1501. Larger electric current limit is determined by the structure of such area, and therefore maximum values of the linewidth and the via diameter are determined by this area. One output and one input interconnect to the pad block generally correspond to one input of the I/O.

A RAM block 1502 generally includes a capacity of about 1 MB. A miniaturization of the interconnect is prioritized over an operating speed through the interconnect, and therefore narrower interconnect is required. A relatively few wider interconnects are included therein, and a power supply and a ground (GND) interconnect are disposed periodically with a size of a memory cell.

A logic block 1503 exhibiting higher performances is a block, in which power supply interconnects are enhanced in cells that requires higher drive efficiency. The architecture of the logic block 1503 is basically similar to an architecture of a standard cell of a gate array. A power supply interconnect is generally enhanced than RAM, though the architecture of the interconnects is similar to that of RAM. It is general that the logic block includes a plurality of couplings between macro circuits, unlike the PLL.

Since stable operation of a power supply, a GND and a capacitor element is prioritized in the PLL block 1504, it is general to have a linewidth of the interconnect that is second broadest, after the line width the interconnect in the I/O region, though the density of the interconnect is not close-packed. The PLL block amplifies signal input from an external transmitter by four to five times and configures clock trees employing such amplified signals in respective macros. Such clock input units and clock output units are drawing interconnects from the macro circuits. There are basically only two input and output interconnects therein.

A structure of a block coupling of macro circuits for two logic units in such general interconnect arrangement structure will be described in reference to FIG. 15.

In FIG. 15, numeral number 1601 indicates a first logic region (macro circuit region), numeral number 1602 indicates second logic region (macro circuit region), and numeral number 1603 indicates a region deposed between macro circuits. A power supply mesh 1604 and a GND mesh 1605 are disposed within the macro circuit. A connecting wire and a signal interconnect 1606, which are circuit structure elements, are disposed between the power supply mesh 1604 and the GND mesh 1605 of the macro circuit. Further, signal interconnects that provide connections between the macro circuits are drawn. Numeral number 1607 indicates such coupling region of the signal interconnects. The macro circuits may be connected via interconnects disposed in the same layer, or alternatively macro circuits may be connected via interconnects disposed in the different layers.

Here, a case of providing a coupling via interconnects disposed in the different layers will be described in reference to FIG. 16. An interconnect layer is composed of a first macro circuit region 1701 and an interconnect region 1702 between macros for providing an electrical coupling to a pad. An insulating film 1704 is formed on a silicon substrate 1703. An M1 interconnect 1705 and an M2 interconnect 1706 are alternately disposed in such region. These interconnects are connected through a via 1707. Here, widths of the M1 interconnect 1705 and the M2 interconnect 1706 are all 70 nm, which are the minimum linewidth in each interconnect layer.

An allowance located in an end of the M1 interconnect 1705 and the via 1707 is referred to an extension 1708.

In such case, a coupling portion is included, and both drawer units of both macros are mutually connected to through a via to form a structure, similarly as in the via chain described above.

It was general in the structure of the related art to have a configuration, in which an interval between an end of the interconnect for connecting a macro circuit and another macro circuit and an adjacent interconnect is wide, similarly as in an isolated interconnect. Therefore, a phenomenon of providing a pulled back-end of the interconnect by reducing the length of the interconnect than the designed length thereof is easily occurred in the process for manufacturing the semiconductor device. A phenomenon of causing an electric disconnection in the structure having an end of an interconnect pulled back from the designed length (condition of FIG. 16) is illustrated in FIG. 17. As shown in FIG. 17, a coupling end of the M1 interconnect 1705 connected to the M2 interconnect 1706 through the via 1707 is pulled back, and when a length of such setback 1808 is larger than the diameter of the via 1707, a disconnection is occurred.

### SUMMARY OF THE INVENTION

Taking the actual situation of the related art described above into consideration, the present invention is to provide a semiconductor device having a configuration, which provides a prevention from a disconnection occurred by a setback of an interconnect that is caused in a microinterconnect having a linewidth of equal to or smaller than 0.1 μm connected through a via.

According to one aspect of the present invention, there is provided a semiconductor device, comprising: a plurality of macro circuits, each of the macro circuits including an interconnect; and a coupling region for coupling ends of the interconnects of the plurality of the macro circuits, wherein the coupling region includes two or more layers of the interconnects having same linewidth, and the ends of the interconnects are connected through a plurality of vias. Having such configuration, a disconnection due to a setback of the end of the interconnect that is caused in the coupling interconnect can be prevented.

Further, the present invention can provide a configuration that achieves inhibiting a generation of the end-setback phenomenon of the coupling interconnect by providing a configuration, in which at least one of dummy interconnect or at least one of dummy via is disposed in a location adjacent to the end of the interconnect, the dummy interconnect or the dummy via having a linewidth, which is the same as the linewidth of the interconnect.

As described above, according to the present invention, a creation of a disconnection due to a phenomenon of causing a setback of the interconnect end against the via during the process for forming a microinterconnect pattern can be prevented in the structure including a configuration of coupling the interconnect end of the lower microinterconnect layer to the interconnect end of the upper microinterconnect layer through the via.

### BRIEF DESCRIPTION OF THE DRAWINGS

The above and other objects, advantages and features of the present invention will be more apparent from the following description taken in conjunction with the accompanying drawings, in which:

FIG. 1 is a plan view of a semiconductor device, useful in describing first embodiment of the present invention;

FIG. 2 is a cross-sectional view of the device along line X-X′ appeared in FIG. 1;

FIG. 3 is a cross-sectional view of the device, useful in describing advantageous effects of first embodiment of the present invention;

FIG. 4 is a graph, showing a dependency in the frequencies of producing a good product and of generating a defective product upon the length of the extension in the related configuration and the configuration according to first embodiment of the present invention;

FIG. 5 is a plan view of the device, useful in describing second embodiment of the present invention;

FIG. 6 is a cross-sectional view of the device along line Y-Y′ appeared in FIG. 5;

FIG. 7 is a general view of a test chip layout for general process evaluation;

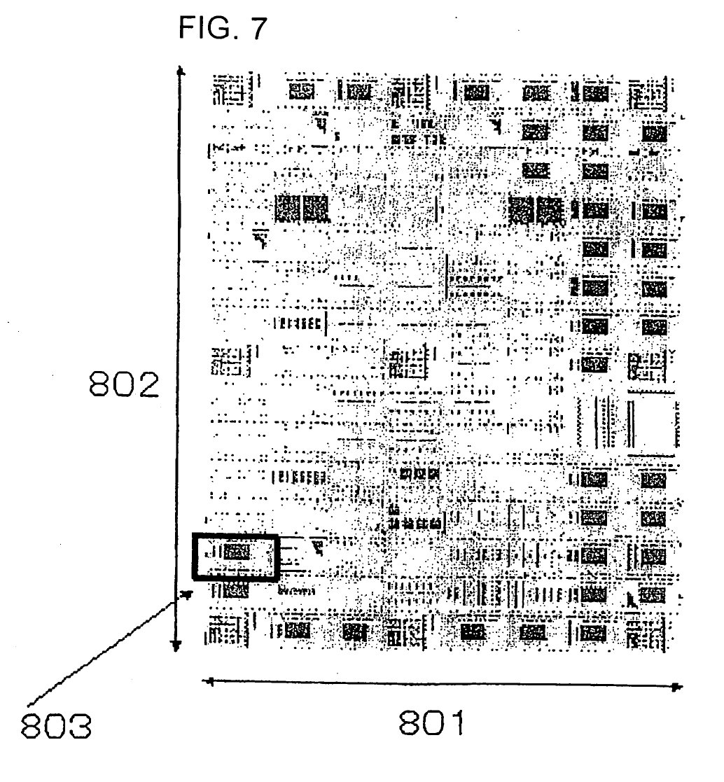

FIG. 8 is an enlarged plan view of a general pattern for evaluating an interconnect process;

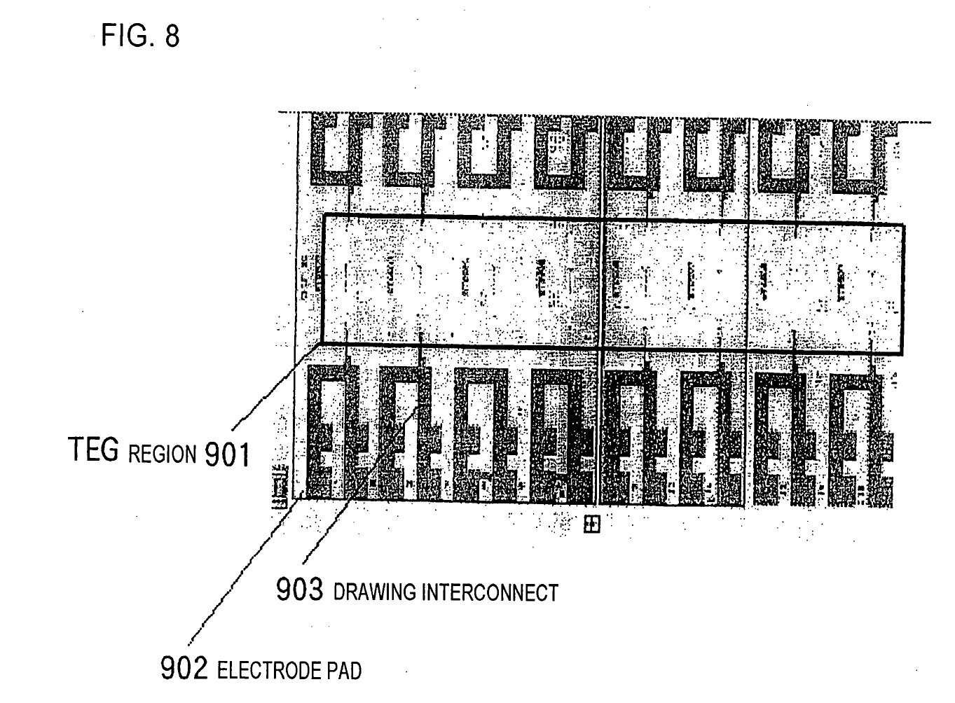

FIG. 9 is an enlarged view of a region for coupling the TEG region with the electrode pad;

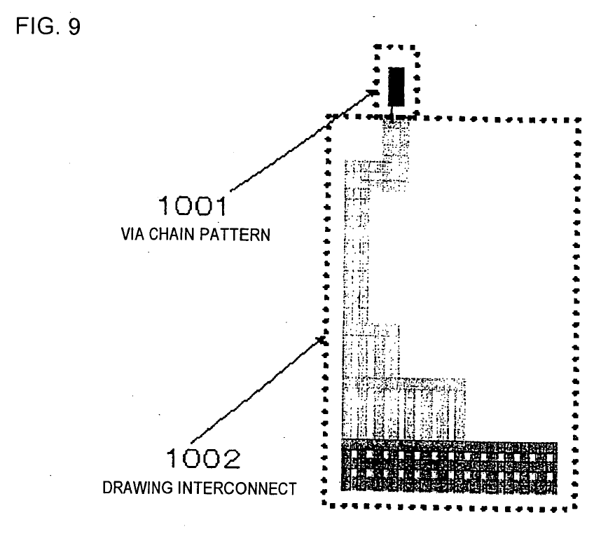

FIG. 10 is an enlarged view of a portion for coupling a via chain pattern with a drawing interconnect shown in FIG. 9;

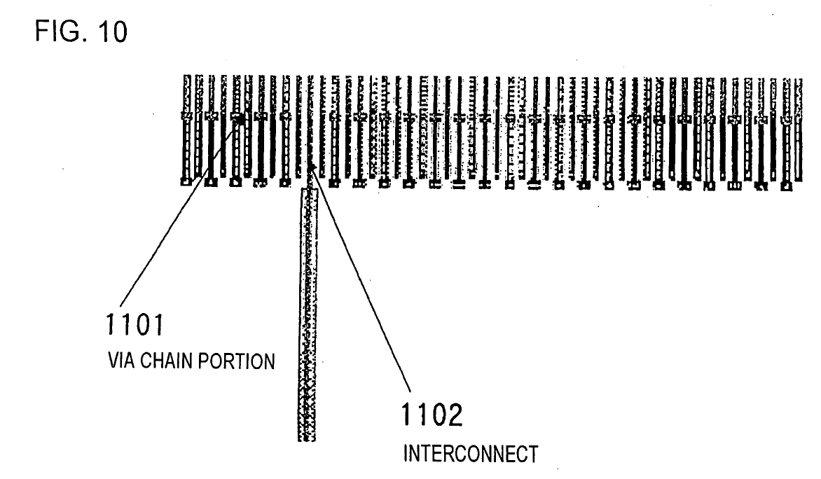

FIG. 11 is an enlarged plan view of an interconnect connected to a designated pad interconnect;

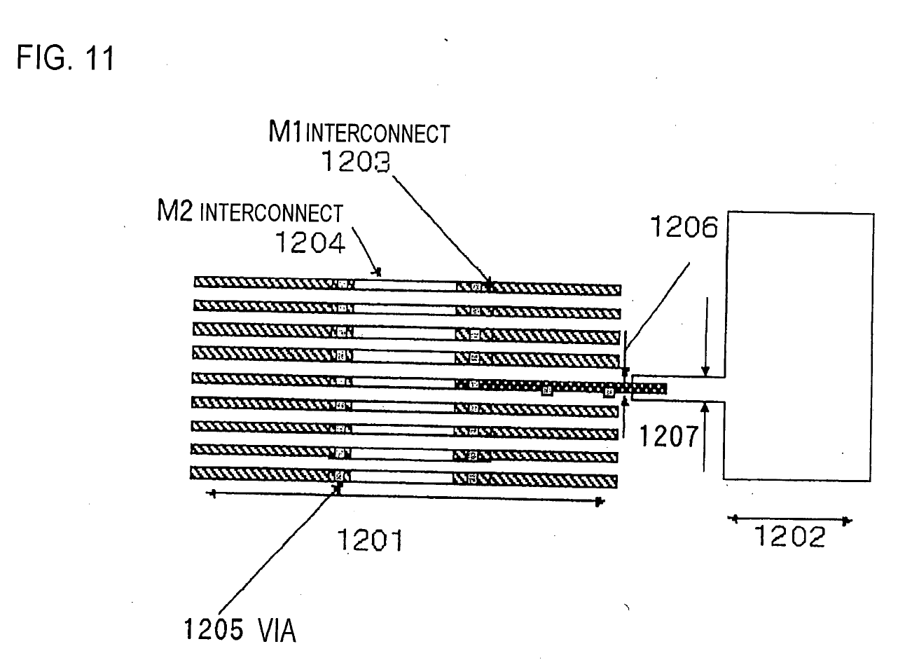

FIG. 12 is a cross-sectional view of an interconnect structure of the related art shown in FIG. 11;

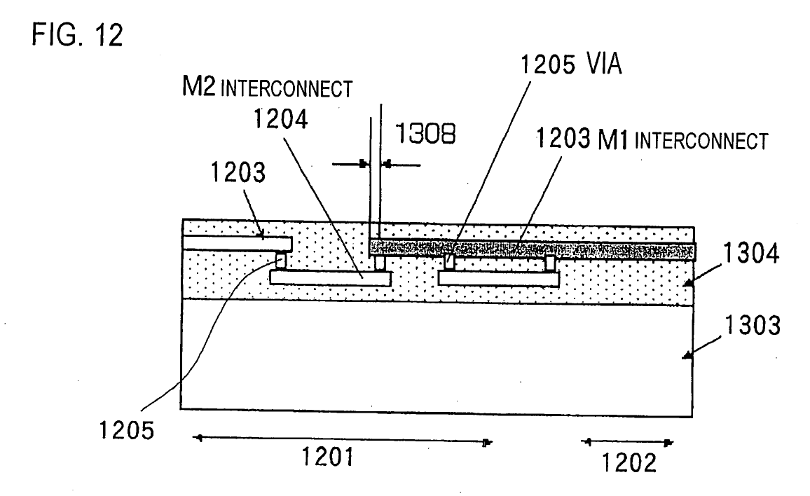

FIGS. 13A to 13E are cross-sectional views of the device, useful in describing a manufacturing process of a generally employed dual layer interconnect;

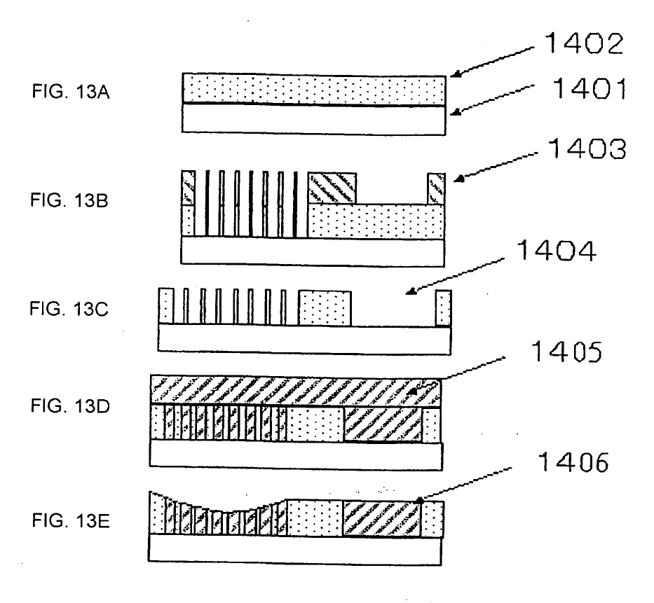

FIG. 14 is a plan view, showing an outline of a type of a general semiconductor device;

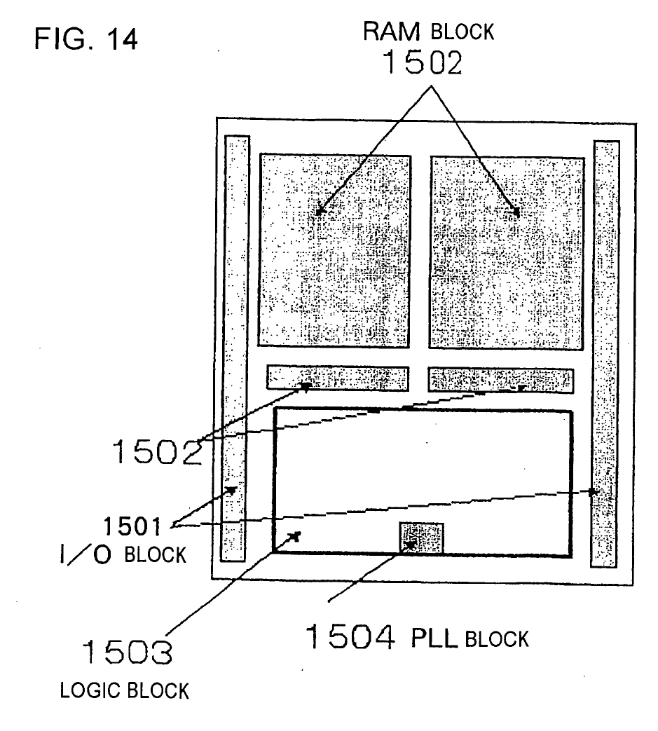

FIG. 15 is a plan view, showing a structure for coupling two macro blocks;

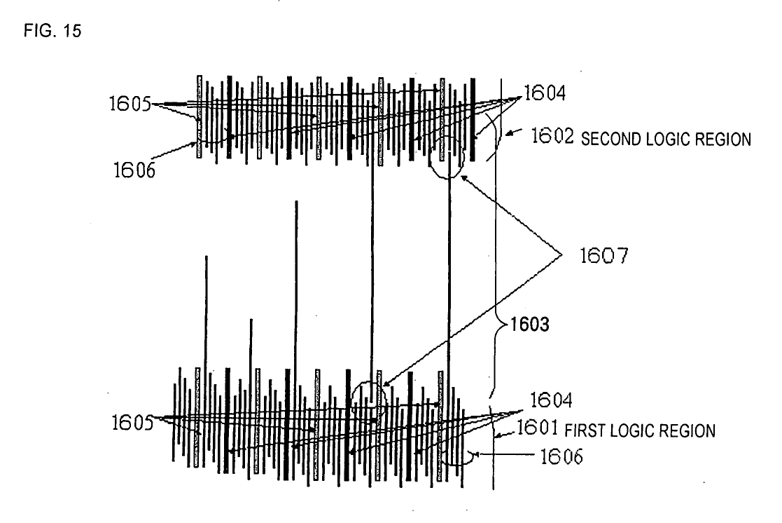

FIG. 16 is a plan view, showing a structure for coupling macro blocks of the related art; and

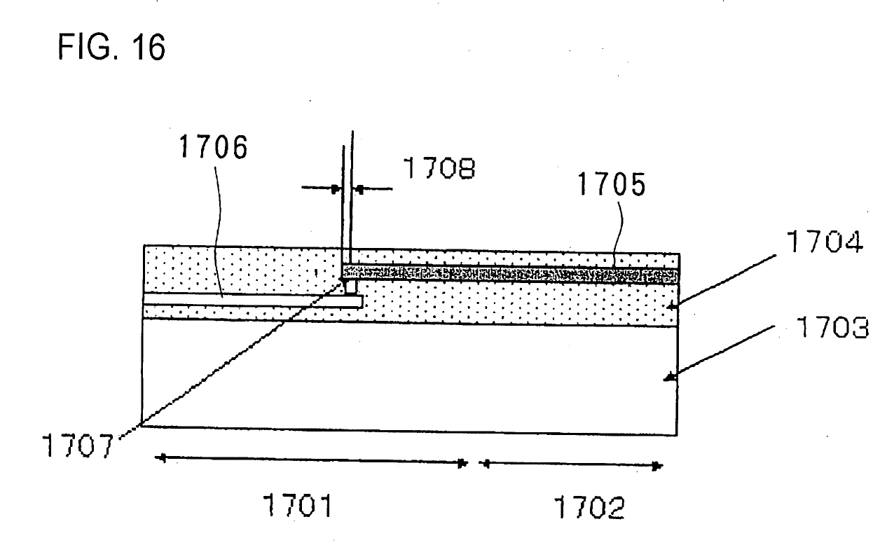

FIG. 17 is a cross-sectional view of the device of the related art, useful in describing a problem to be solved by the present invention.

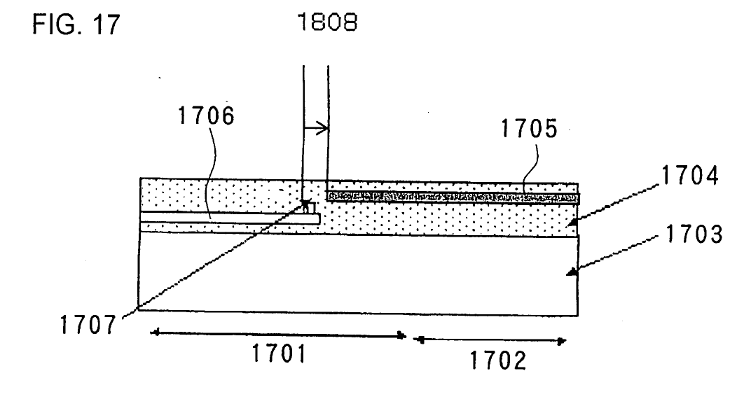

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable embodiments according to the present invention will be described as follows in further detail, in reference to the annexed figures.

### First Embodiment

An exemplary implementation of a TEG for process evaluation will be illustrated in first embodiment of the present invention.

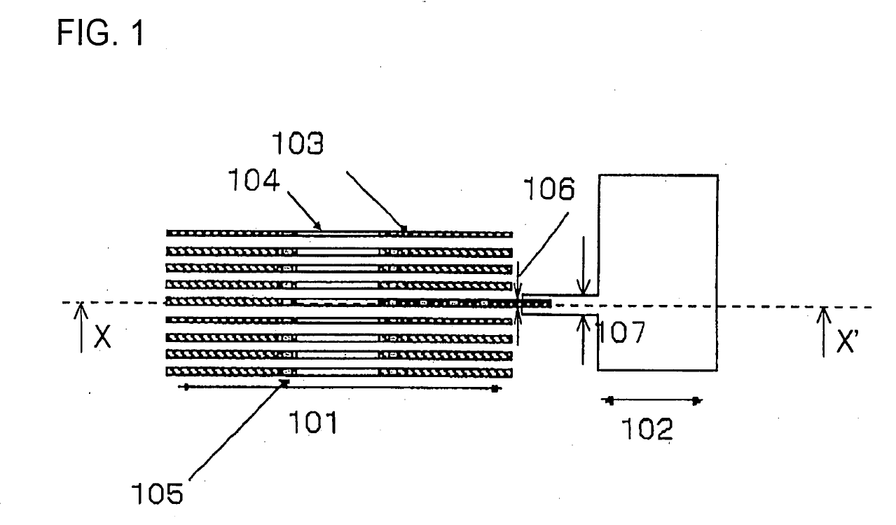

FIG. 1 illustrates an enlarged plan view of an interconnect for providing a coupling to a pad interconnect as first embodiment. A test pattern is composed of a TEG region 101 for evaluating a via chain and a drawing interconnect region 102 for providing an electrical coupling to a pad. The TEG region 101 is formed of a structure, in which an M1 interconnect 103 and an M2 interconnect 104 are alternately disposed and these interconnects are connected through the vias 105. Here, widths of the M1 interconnect 103 and the M2 interconnect 104 are all 70 nm for example, which is the minimum linewidth in the interconnect layer indicated by a numeral number of 106. However, the linewidth of the M1 interconnect 103 and the M2 interconnect 104 may not be 70 nm, and the linewidth is acceptable also within the range of 50-140 nm. More suitably, this range is 100 nm or less. The linewidth of the M1 interconnect 103 connected to the pad is the minimum linewidth 106 in a coupling end of the interconnect. Further, an isolated interconnect unit is stepwise increased in a portion disposed as a single interconnect, and the linewidth of such portion around 0.17 μm for example.

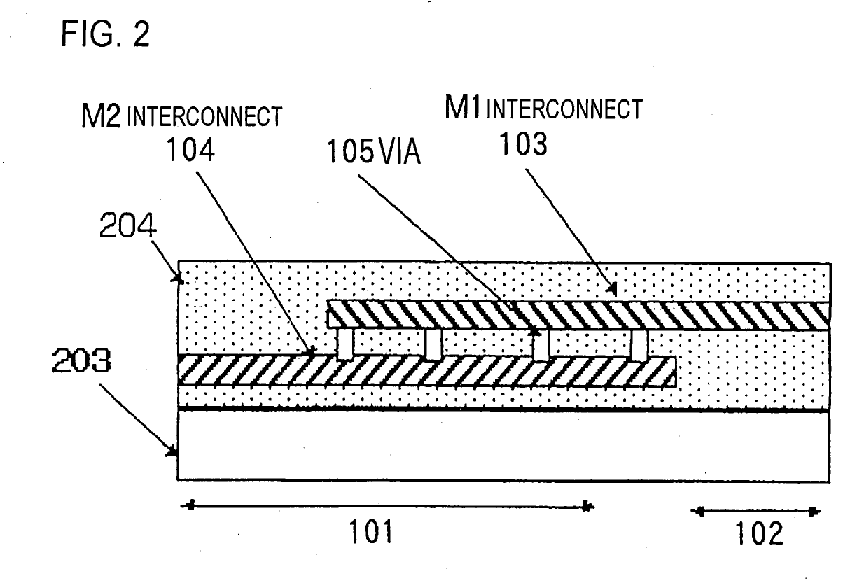

A cross-sectional view along line X-X′ shown in FIG. 1 is illustrated in FIG. 2. An interconnect layer of a test pattern is composed of a via chain evaluation TEG region 101 and a drawing interconnect region 102 for providing an electrical coupling to the pad. An insulating film 204 is formed on a silicon substrate 203. An M1 interconnect 103 and an M2 interconnect 104 are alternately disposed in such region. These interconnects are connected through vias 105. Here, widths of the M1 interconnect 103 and the M2 interconnect 104 are same 70 nm for example, and which are the minimum linewidth that is minimum linewidth on design of the specification in the circuit block. Characteristics of such structure are that the via 105 has a width, which is the same as the linewidth of the M1 interconnect 103 and the M2 interconnect 104, and that the M1 interconnect 103 and the M2 interconnect 104 are commonly connected through a plurality of vias 105. It is critical in the configuration according to the present embodiment that the M1 interconnect 103 is connected to the M2 interconnect 104 having the same linewidth as that of M1 through a plurality of via 105. The linewidth of the M1 interconnect 103 and the M2 interconnect 104 are the same as the width of the vias 105 in a design size, with an error of about ±10% in the manufactured product.

Advantageous effects obtainable by employing the configuration according to the present embodiment will be described.

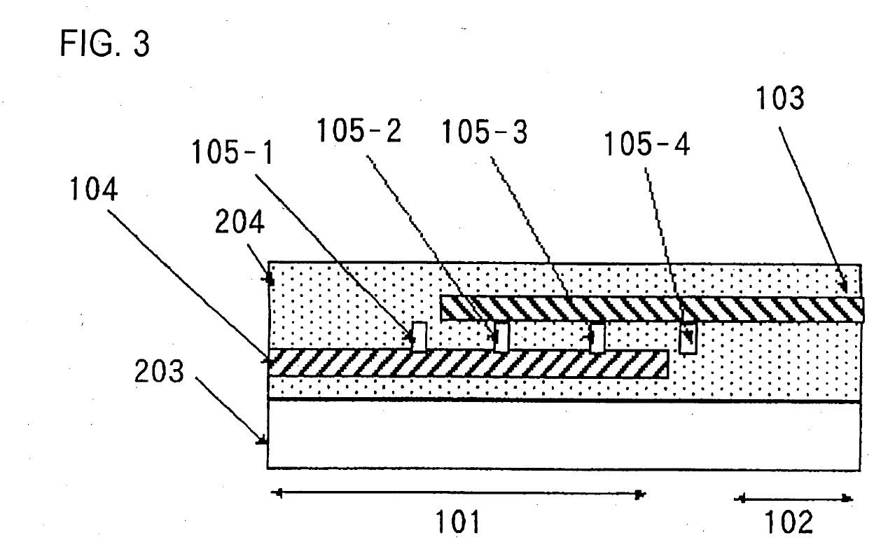

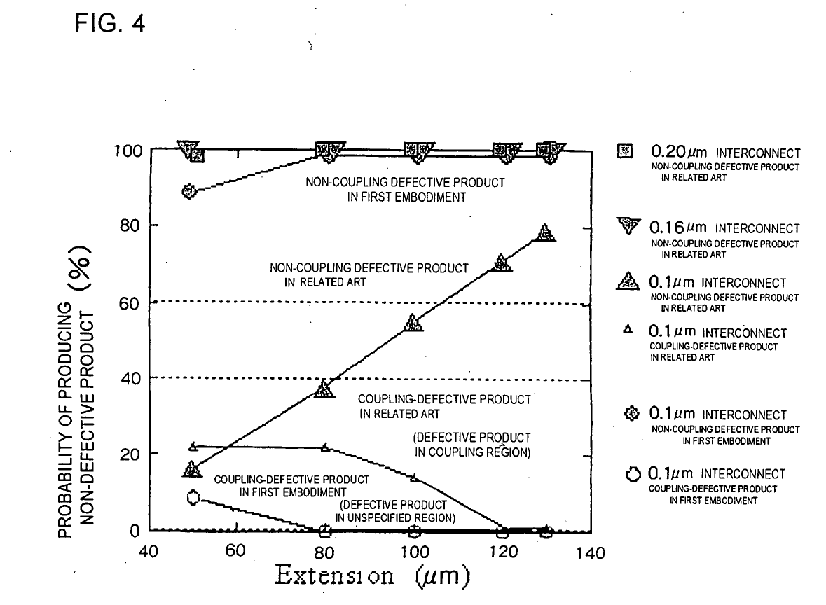

A cross-sectional view showing a condition, in which an interconnect is pulled back, is shown in FIG. 3. For example, if the linewidth is 140 nm, the Vias 105 with a diameter of 140 nm will be arranged at intervals of 140 nm. In that case, if four the Vias 150 are arranged, the overlap length of the M1 and the M2 can be set to about 980 nm, summation of the interval of four the Vias 150 and width of two the Vias 150. If the linewidth is 50 nm, the Vias 105 with a diameter of 50 nm will be arranged at intervals of 50 nm. In that case, if four the Vias 150 are arranged, the overlap length of the M1 and the M2 can be set to about 350 nm, summation of the interval of four the Vias 150 and width of two the Vias 150. An end of the M1 interconnect 103 is pulled back to cause a disconnection of a via 105-1, and an end of the M2 interconnect 104 is pulled back to cause a disconnection of a via 105-4. Nevertheless, the M1 interconnect 103 is connected to the M2 interconnect 104 through the via 105-2 and the via 105-3. More specifically, a structure is offered, which avoids a disconnection of the interconnect even if a setback of the interconnect is caused, by providing a configuration of simultaneously coupling upper and lower interconnects in parallel through a plurality of vias in the interconnect coupling portion. Larger number of such vias provides more stable process. Dependency of a failure distribution upon a length of an allowance (extension) in the length of the interconnect end is shown in FIG. 4. While no defective product is generated when a linewidth is not smaller than 0.16 μm in the structure of the related art, defective products having a failure in the coupling region occupy the majority when the linewidth is equal to or smaller than 0.1 μm, though failure is decreased depending on the length of the extension. As described above, while larger amount of defective products are generated when the interconnect having a linewidth of equal to or less than 0.1 μm is employed in the structure of the related art, rate of generating defective products is reduced the interconnect having a linewidth of equal to or less than 0.1 μm is employed in the structure according to first embodiment of the present invention, which involves employing a plurality of vias. Further, smaller level of the additional allowance for the end of the interconnect provides more efficient improvement in the coupling failure.

### Second Embodiment

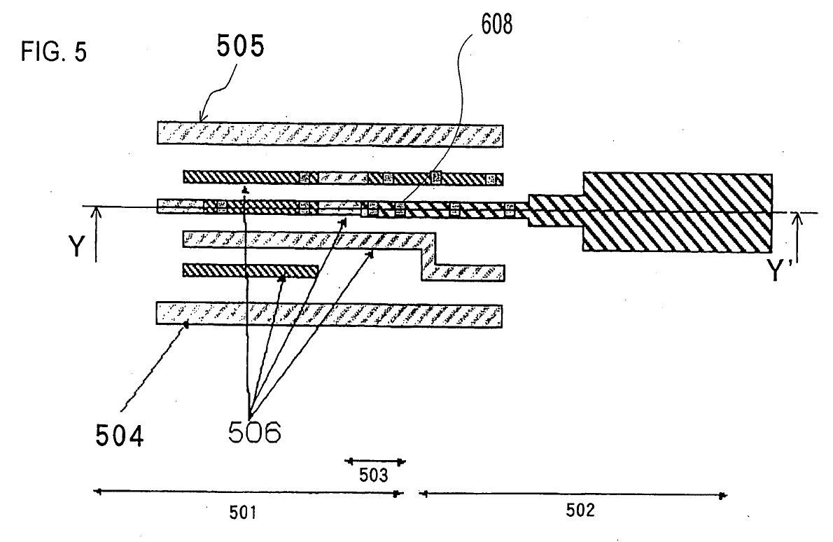

In this embodiment, an exemplary implementation of a finished product including a structure of coupling blocks in two macro circuits in logic units will be described in reference to FIG. 5.

In FIG. 5, numeral number 501 indicates a first logic region (macro circuit region), and numeral number 502 indicates a region disposed between the first logic region 501 and a second logic region (not shown) (region between macro circuits). Here, widths of vias 608 is 70 nm for example. However, the width may not be 70 nm, and is acceptable also within the range of 50-140 nm. More suitably, this range is 100 nm or less. A power supply mesh 504 and a GND mesh 505 are disposed within the macro circuit. A connecting wire and a signal interconnect 506, which are circuit structure elements, are disposed between the power supply mesh 504 and the GND mesh 505 of the macro circuit. Further, signal interconnects that provide connection between the macro circuits are provided in the region between macro circuits 502. Numeral number 503 indicates such coupling region for the signal interconnect.

For example, if the linewidth is 140 nm, the Vias 608 with a diameter of 140 nm will be arranged at intervals of 140 nm. In that case, if four the Vias 608 are arranged, the overlap length of the M1 and the M2 can be set to about 980 nm, summation of the interval of four the Vias 608 and width of two the Vias 608. If the linewidth is 50 nm, the Vias 608 with a diameter of 50 nm will be arranged at intervals of 50 nm. In that case, if four the Vias 608 are arranged, the overlap length of the M1 and the M2 can be set to about 350 nm, summation of the interval of four the Vias 608 and width of two the Vias 608.

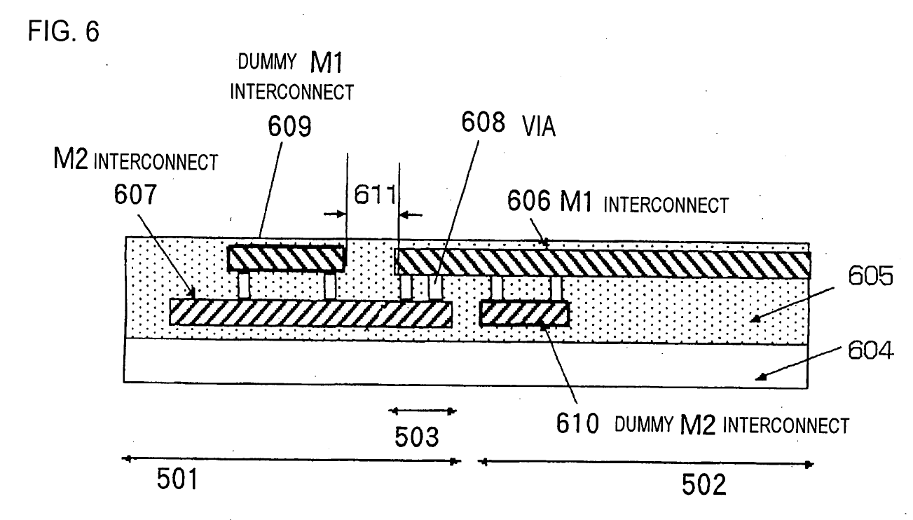

A cross-sectional view cut along line Y-Y′ appeared in FIG. 5 is shown in FIG. 6, and further description will be made in detail in reference to FIG. 6. As shown in the cross-sectional view of FIG. 6, an insulating film 605 is formed on a silicon substrate 604. An M1 interconnect 606 and an M2 interconnect 607 are alternately disposed in such region. These interconnects are connected through vias 608. Here, widths of the M1 interconnect 606 and the M2 interconnect 607 are all 70 nm for example, and which are the minimum linewidth that is the minimum linewidth. However, the width of the interconnects 606 and 607 and the via 608 may not be 70 nm, and the linewidth is acceptable also within the range of 50-140 nm. More suitably, this range is 100 nm or less. Two vias 608 are disposed for coupling the M1 interconnect 606 to the M2 interconnect 607. The width of the via 608 is the same as the widths of the M1 interconnect 606 and the M2 interconnect 607. Further, a dummy M1 interconnect 609 having a width same as the width of the M1 interconnect 606 is disposed to form an interval with the end of the interconnect for coupling to the M2 interconnect 607 in the M1 interconnect 606, which is equivalent to the minimum interconnect interval 611 (minimum interval between the interconnects of circuit block on design specification). The dummy M1 interconnect 609 is connected to the M2 interconnect 607 through two dummy vias. Further, a dummy M2 interconnect 610 having a width same as the width of the M2 interconnect 607 is disposed to form an interval with the end of the interconnect for coupling to the M1 interconnect 606 in the M2 interconnect 607, which is equivalent to the minimum interconnect interval 611. The dummy M2 interconnect 610 is connected to the M1 interconnect 607 through two dummy vias. The width of each of dummy vias is the same as the widths of the M1 interconnect 606 and the M2 interconnect 607. The linewidth of the M1 interconnect 607 and the M2 interconnect 610 is the same as the width of the vias 608. This same of the linewidth is same of the design size. Even if the design size is the same, about ±10% of error may be in the manufactured product.

Next, advantageous effects obtainable by employing the configuration according to the present embodiment will be described. In this embodiment, an advantageous effect of reducing a setback phenomenon of the interconnect end is exhibited by arranging the dummy interconnect to form the interval with the microinterconnect in the coupling region, which is equivalent to the minimum interconnect interval.

It is apparent that the present invention is not limited to the above embodiment, that may be modified and changed without departing from the scope and spirit of the invention.

What is claimed is:

1. A semiconductor device, comprising:
a plurality of macro circuits, each of said macro circuits including an interconnect; and
a coupling region for coupling ends of the interconnects of said plurality of the macro circuits,
wherein said coupling region includes two or more layers of said interconnects having same linewidth, and the ends of said interconnects are connected through a plurality of vias.

2. The semiconductor device according to claim 1, wherein said interconnect and said via are formed to have a linewidth, which is equivalent to the minimum linewidth in the macro circuit.

3. The semiconductor device according to claim 1, wherein said interconnect and said via are formed to have a linewidth of equal to or smaller than 0.1 μm.

4. The semiconductor device according to claim 1, wherein at least one dummy interconnect or at least one dummy via is disposed in a location adjacent to the end of said interconnect, said dummy interconnect or said dummy via having a linewidth, which is the same as the linewidth of said interconnect.

5. The semiconductor device according to claim 4, wherein said dummy interconnect or said dummy via is arranged to form a spacing with the end of said interconnect, said spacing being equivalent to minimum interconnect interval in the macro circuit.

6. The semiconductor device according to claim 4, wherein said dummy interconnect or said dummy via is formed to have a linewidth, which is equivalent to a minimum linewidth in the macro circuit.

7. The semiconductor device according to claim 4, wherein said dummy interconnect or said dummy via is formed to have a linewidth of equal to or smaller than 0.1 μm.

8. A semiconductor device, comprising:
a first interconnect;
a second interconnect having a linewidth that is the same as the line width of said first interconnect, an end of said second interconnect being disposed above the end of said first interconnect; and
a plurality of via for coupling the end of said first interconnect to the end of said second interconnect.

9. The semiconductor device according to claim 8, wherein said plurality of vias are arranged along a longitudinal direction of said interconnect.

10. The semiconductor device according to claim 8, wherein said device comprises a first macro circuit having said first interconnect and a second macro circuit having said second interconnect.

11. The semiconductor device according to claim 8, wherein said first interconnect, said second interconnect and said via are formed to have a linewidth, which is equivalent to minimum linewidth of said first macro circuit and said second macro circuit.
